(19) United States
(12) Patent Application Publication
(10) Pub. No.: US 2014/0210603 A1
(43) Pub. Date: Jul. 31, 2014

(54) FLUID LEAKAGE DETECTION SYSTEM FOR VEHICLES

(71) Applicant: FORD GLOBAL TECHNOLOGIES, LLC, DEARBORN, MI (US)

(72) Inventor: ANTHONY RICHARD WALSER, ROYAL OAK, MI (US)

(73) Assignee: FORD GLOBAL TECHNOLOGIES, LLC, DEARBORN, MI (US)

(21) Appl. No.: 13/753,552

(22) Filed: Jan. 30, 2013

(51) Int. Cl. G01R 27/02; B60Q 9/00; G01M 3/40

(52) U.S. Cl. CPC G01R 27/02; G01M 3/40; B60Q 9/00
USPC 340/438; 324/691

(57) ABSTRACT

A fluid leakage detection system includes a fluid leakage sensor and an alarming system. The fluid leakage sensor is electrically coupled to the alarming system, and is configured to send signals pertaining to any detected fluid leakage. Further, the fluid leakage sensor includes an electrically non-conductive body and an electrical circuit. The non-conductive body is positioned proximal to a leakage region and it collect and absorbs leaking fluid from the region. The electric circuit includes a first portion embedded within the non-conductive body, and a second portion connected to the first portion. The second portion of the electrical circuit lies exterior to the non-conductive body. The electrical circuit is open-circuited under no fluid leakage detection conditions, and is closed-circuited under leakage detection conditions. The alarm system is configured to generate an alarm signal when the electric circuit is closed-circuited.

### TECHNICAL FIELD

Embodiments of the present disclosure generally relate to automotive vehicles, and, more specifically, to fluid leakage detection systems integrated to automotive vehicles.

### BACKGROUND

Fluid leakage is a common problem in buildings, appliances, vehicles, etc. In automotive vehicles, places where fluid may enter a vehicle are often difficult to see for the locations may be hidden behind floor coverings and hard plastic trim. Undetected fluid leakage in vehicles may cause damage to portions of a vehicle, including the electrical systems installed in the vehicle. Further, prolonged fluid leakage can result in accumulation of fluid in the vehicle, which can cause even more damage. The accumulated fluid can take a long time to evaporate. Removing these large volumes of fluid is inconvenient and expensive for it may require removing carpets and using suction methods. Fluid leakage in vehicles can cost owners and property insurers millions of dollars every year. Therefore, to prevent damage caused by fluid leakages, it is desirable to install fluid leakage detection systems in vehicles.

There are several kinds of conventional systems available for fluid leakage detection. Such systems typically include a sensor and an alarm system coupled to the sensor. The sensor transmits a signal to the alarm system on detecting fluid leakage. Many of the conventional fluid leakage sensors incorporated in vehicles can't detect small volumes of fluid leakage. Specifically, most fluid leaks are detected only after a substantial amount of fluid accumulation. This causes a problem as the user is notified of the fluid leakage long time after the onset of the fluid leakage. Further, existing fluid leakage sensors are not flexible, and cannot be installed on contoured surfaces within vehicles.

Considering the aforementioned problems, a need exists for a leakage detection system that can detect even minute volumes of fluid leakage in vehicles, even if the fluid leaks are in the form of small droplets. Further, the leakage detection system should be flexible so the system can be installed on contoured surfaces within the vehicle.

### SUMMARY

The present disclosure provides a fluid leakage detection system for automotive vehicles. The system can be easily installed on contoured surfaces within the vehicle, and is capable of detecting even small volumes of leaking fluid at any location in the vehicle.

According to an aspect, the present disclosure provides a fluid leakage detection system having a fluid leakage sensor. The fluid leakage sensor includes an electrically non-conductive body and an electrical circuit coupled to the non-conductive body. The non-conductive body is composed of an absorbent material, and is positioned to collect and absorb a leaking electrically conductive fluid. The electrical circuit includes a first portion and a second portion. The first portion of the electrical circuit is embedded in the non-conductive body, and the second portion is positioned exterior to the non-conductive body. The second portion is coupled to an alarming system. The electrical circuit is open-circuited when no fluid leakage is detected, and is closed-circuited by the electrically conductive fluid, when the fluid leaks. A signal is transmitted from the electrical circuit to the alarming system when the electrical circuit is closed circuited. The alarming system generates an alarm signal when it receives a signal from the electrical circuit, and notifies the fluid leakage to a user.

According to another aspect, the present disclosure provides a fluid leakage detection system for detecting leakage of an electrically conductive fluid from one or more portions of a vehicle. The system includes an electrically non-conductive body formed of an absorbent material, positioned to collect and absorb the electrically conductive fluid leaking from one or more portions of the vehicle. An electrical circuit is coupled to the non-conductive body, and it includes a first portion and a second portion. The first portion of the electrical circuit is embedded in the non-conductive body, to continuously maintain contact with the non-conductive body. The second portion of the electrical circuit lies exterior to the non-conductive body, and is coupled to an alarming system. The electrical circuit is kept open circuited when no fluid leakage is detected. Further, the electrical circuit is kept closed-circuited when any fluid leakage is detected. The alarming system generates a signal notifying leakage of the fluid, when the electrical circuit is closed-circuited.

Additional aspects, advantages, features and objects of the present disclosure would be made apparent from the drawings and the detailed description of the illustrative embodiments construed in conjunction with the appended claims that follow.

### BRIEF DESCRIPTION OF THE DRAWINGS

FIG. 1 is a schematic view of a fluid leakage detection system having a fluid leakage sensor coupled to an alarm system, in accordance with the present disclosure.

FIG. 2 is another schematic view of the fluid leakage detection system of FIG. 1, illustrating the pattern of distribution of a portion of an electrical circuit within a non-conductive body of the fluid leakage detection system, according to an embodiment of the present disclosure.

FIG. 3 is a schematic view of a fluid leakage sensor including a non-conductive body and an electrical circuit, depicting an insulated circumferential portion of the non-conductive body, in accordance with an embodiment of the present disclosure.

FIG. 4 depicts a fluid leakage detection system having a multiple fluid leakage sensors installed at different regions within the vehicle, each sensor being coupled to a central alarm system, according to an embodiment of the present disclosure.

FIG. 5 is a side view of a vehicle, having the fluid leakage detection system of FIG. 1 disposed at different portions of the vehicle, according to an embodiment of the present disclosure.

### DETAILED DESCRIPTION OF ILLUSTRATIVE EMBODIMENTS

The following detailed description illustrates aspects of the disclosure and the ways it can be implemented. However, the description does not define or limit the invention, such definition or limitation being solely contained in the claims appended thereto. Although the best mode of carrying out the invention has been disclosed, those in the art would recognize that other embodiments for carrying out or practicing the invention are also possible.

The present disclosure provides a system for detecting fluid leakage within a vehicle. The fluid leakage detection system includes one or more fluid leakage detection sensors and a central alarming system. The system is capable of detecting even minute volumes of leaking fluid, which may be in the form of drops having a volume on the order of about 0.05 ml. Due to this sensitivity, the system helps prevent damage caused to portions of vehicle by unidentified leaking fluid accumulating over long periods of time. The fluid leakage detection system is also flexible enough to be installed on contoured surfaces of the vehicle, eliminating the problems faced by conventional fluid leakage detection systems.

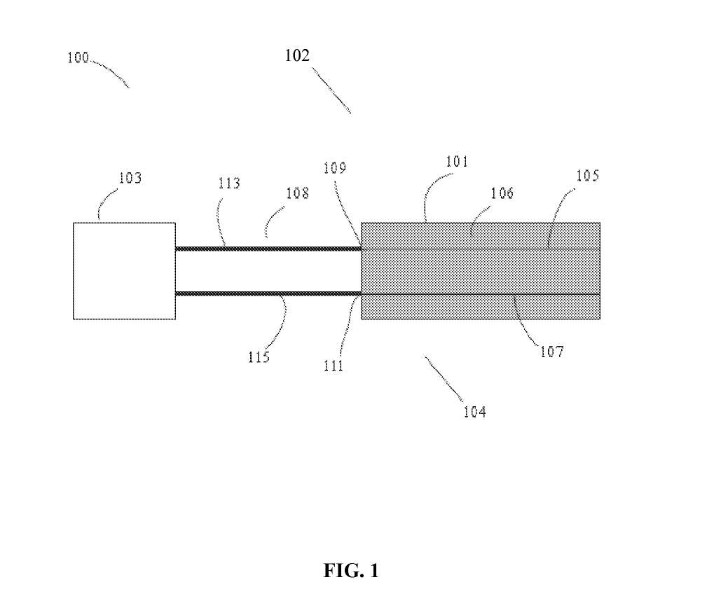

FIG. 1 shows a fluid leakage detection system 100, according to an embodiment of the present disclosure. The fluid leakage detection system 100 includes a fluid leakage sensor 102 and an alarming system 103. The fluid leakage sensor 102 is electrically coupled to the alarming system 103 and is configured to send electrical signals to the alarming system 103, on detecting even minute volumes of leaking fluid. The fluid leakage sensor 102 may be installed in any portion of a vehicle where fluid leakage is likely to occur, or where monitoring and preventing fluid leakage is desired. Typical, but not exhaustive, of such locations around joints, behind sealed openings, under the floor of the vehicle, and similar locations

The fluid leakage sensor 102 includes a non-conductive body 101 and an electrical circuit 104. The non-conductive body 101 maintains consistent contact with a potential fluid leakage region, and it collects and absorbs fluid leaking from that region. Further, the non-conductive body 101 is formed of an appropriate absorbent material, to absorb fluid leaking from the fluid leakage region. In an embodiment, the non-conductive body 101 may be composed of woven fibers, felted fibers or polymeric foam. However, it is contemplated that other suitable absorbent materials may also be used to form the non-conductive body 101 in certain embodiments. Further, the non-conductive body 101 may be impregnated with a non-aqueous soluble salt for increasing the conductivity of the fluid absorbed in the non-conductive body 101. Also, the material of composition of the body 101 is electrically non-conductive. The electrical circuit 104 includes at least two conductive members. The conductive members may be formed of any of the known and available devices known to the art for this purpose, such as electrical wires, electrically conductive threads, metallic strips, and similar devices. Conductive members will be referred to as “wires” below, for convenience.

The electrical circuit 104 of the fluid leakage sensor 102 includes a first portion 106 and a second portion 108. The first portion 106 is embedded within the non-conductive body 101, and thus, it continuously maintains contact with the body, while the second portion 108 lies exterior to it. The two portions 106 and 108 of the electrical circuit 104 are connected to, and electrically coupled with each other. The first portion 106 is formed of at least two uninsulated (i.e., bare) wires 105, 107, as shown. These wires are spread within the non-conductive body 101 in a predetermined pattern, allowing them to maintain contact with the non-conductive body 101. A specific minimum pre-determined distance is maintained between the uninsulated wires 105, 107, at all portions of the non-conductive body 101. The pre-determined distance may vary, based on the size and shape of the non-conductive body 101. That separation enables electrical decoupling between them when no fluid leakage occurs, as will be explained in further detail, below. Further, being spread over the surface of the non-conductive body 101, the uninsulated wires 105, 107 cover a substantial portion of the surface area of the non-conductive body 101.

The second portion 108 of the electrical circuit 104 lies exterior to the non-conductive body 101, and it includes two insulated electrical wires 113 and 115 extending outwards from the non-conductive body 101, as shown. Specifically, the insulated wire 113 extends further from the end portion 109 of the uninsulated electrical wire 105, and similarly, the insulated wire 115 extends further from the end portion 111 of the uninsulated electrical wire 107. The second portion 108 of the electrical circuit 104 may be exposed to a metallic surface of the vehicle where the leakage detection system 100 is disposed. For that reason, wires 113 and 115 of the second portion 108 of the electrical circuit 104 are kept insulated. One end of each of the insulated electrical wires 113 and 115 is connected to an alarming system 103, in a suitable manner.

The electrical circuit 104 of the fluid leakage sensor 102 receives power from a power source of the vehicle, such as the vehicle battery (not shown). In a preferred embodiment, a common power source supplies electrical power to the electrical circuit 104 and the alarm system 103. The terminals of the power supply source are connected to the ends of the insulated wires 113 and 115. The power source supplies constant power to the electrical circuit 104, and maintains a potential difference between the electrical wires of the first portion 106 and the second portion 108 of the electrical circuit 104. Further, as mentioned earlier, the uninsulated wires 105, 107 of the first portion 106 of the electrical circuit 104 are separated from each other at all portions of the non-conductive body 101, to keep these uninsulated wires 105, 107 electrically decoupled from each other when no fluid leakage occurs. The electric decoupling of the uninsulated wires 105, 107 prevents a current flow from the wire at higher potential, which may be either of the wires 105 or 107, to the wire at lower potential (the other wire 105, or 107). Specifically, when no fluid leakage occurs, the non-conductive body 101 remains dry, as no leaking fluid is absorbed by it, and the uninsulated wires 105, 107 remain electrically decoupled from each other. This keeps the electrical circuit 104 open-circuited under no leakage detection conditions.

Where fluid leakage occurs, the drops of leaking fluid are absorbed by portions of the non-conductive body 101 positioned proximate to or underneath the leakage ports. After being absorbed, the fluid disperses throughout the non-conductive body 101. Since the uninsulated wires 105, 107 maintain continuous contact with the non-conductive body 101, these wires eventually are exposed to the absorbed fluid, and that fluid may accumulate to the point of bridging the uninsulated wires 105, 107. If the fluid is a good conductor of electricity, such as water, current will flow between the wires 105 and 107. The electric coupling between the uninsulated wires 105, 107 closes the circuit between the first portion 106 and the second portion 108 of the electrical circuit 104. That event energizes the alarming system 103, which generates a signal notifying fluid leakage to the occupants of the vehicle. In an embodiment, the alarming system 103 may be any suitable acoustic alarm known in the art, or a user display interface disposed at an appropriate portion of the vehicle, to display verbal messages corresponding to fluid leakage detection. Further, the alarming system 103 may generate a continuously blinking beep accompanied by an alarm sound, for warning the user, if fluid leakage at a specific portion of the vehicle is detected.

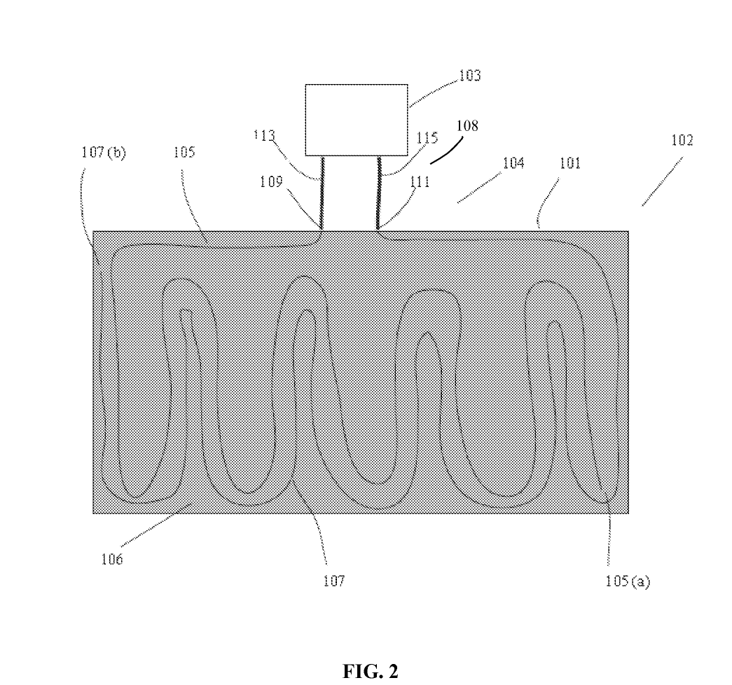

FIG. 2 is a schematic view of a fluid leakage detection system, depicting the pattern of spread of the uninsulated wires 105, 107, according to an embodiment of the present disclosure. As shown, the uninsulated wires 105, 107 are completely embedded in the non-conductive body 101. The non-conductive body 101 is virtually divided into multiple regions. The wires 105, 107 are spread arranged in a sinuous, curving pattern across the non-conductive body 101 such portions of each of the two wires 105, 107 overlie portions of each region

The pattern may be a sinusoidal pattern a common irregular pattern, or any other suitable pattern, predetermined to ensure that a specific minimum distance is maintained between the wires 105, 107 over all portions of the non-conductive body 101 As a result, even a drop of minute volume falling on any portion of the non-conductive body 101 electrically couples the uninsulated wires 105, 107. Those of skill in the art will understand the techniques required to choose an appropriate spacing between uninsulated wires 105, 107 as well as techniques for designing an appropriate pattern across the surface of non-conductive body 101.

The dimensions of the non-conductive body 101 depend on the size of the fluid leakage source. For example, a thin rectangular non-conductive body 101 may be employed to cover a relatively long leakage region. However, other alternatively shaped and sized non-conductive bodies may also be contemplated, depending on factors such as the surface of the vehicle where the leakage detection system is configured to be positioned, as well as the area of that region. In certain embodiments, the non-conductive body 101 may be impregnated with a non-aqueous soluble salt, to increase the conductivity of leaking fluid absorbed by the body.

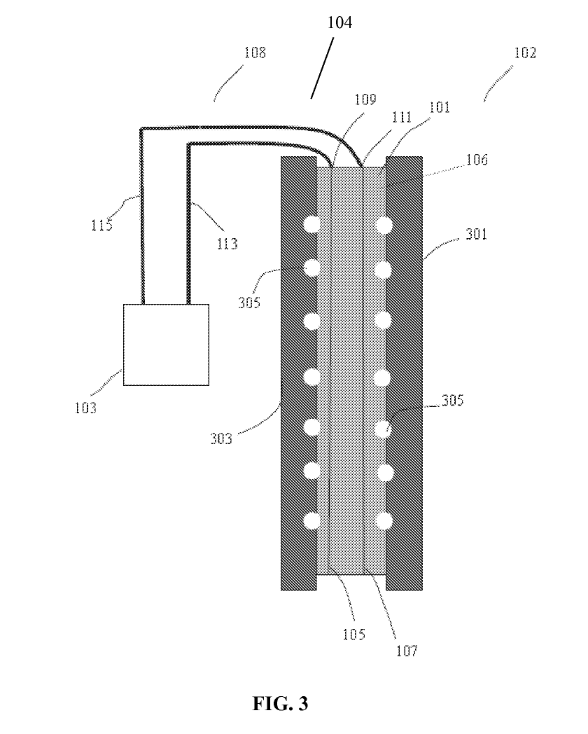

FIG. 3 is a schematic view of an alternative fluid leakage detection system 100. In this embodiment, fluid leakage sensor 102, alarming system 103, non-conductive body 101, and the electrical circuit 104 are provided with basically the same components the structure, shape, and properties as set out above. Thus, these elements will not be explained in detail here.

In the depicted embodiment, the peripheral portion of the non-conductive body 101 is covered with adhesive tape. The tape attaches and positions the non-conductive body 101 proximate to or underneath a potential fluid leakage region. However, other suitable means for attaching the non-conductive body 101 in the region of fluid leakage may also be used. Specifically, two adhesive tape strips of 301 and 303 cover the peripheral portion of the non-conductive body 101, having multiple openings 305 over the strips' surface. These openings 305 leaking fluid to penetrate through to non-conductive body 101.

Where the leaking fluid falls over the peripheral portion of the non-conductive body if it encounters strips 301 and 303, but portions of the fluid flow-through openings 305 and dispersed within the non-conductive body 101. Strips 301, 303 301, 303 may be formed of a porous material, allowing any leaking fluid to pass through them and enter the non-conductive body 101. Effectively, as mentioned earlier, even a minute drop of leaking fluid falling over any portion of the non-conductive body 101, including the peripheral portion, will be absorbed by the non-conductive body 101 and will eventually connect the uninsulated wires 105, 107. Therefore, the fluid leakage detection system 100 of the present disclosure can detect even extremely minute volumes of fluid leakage.

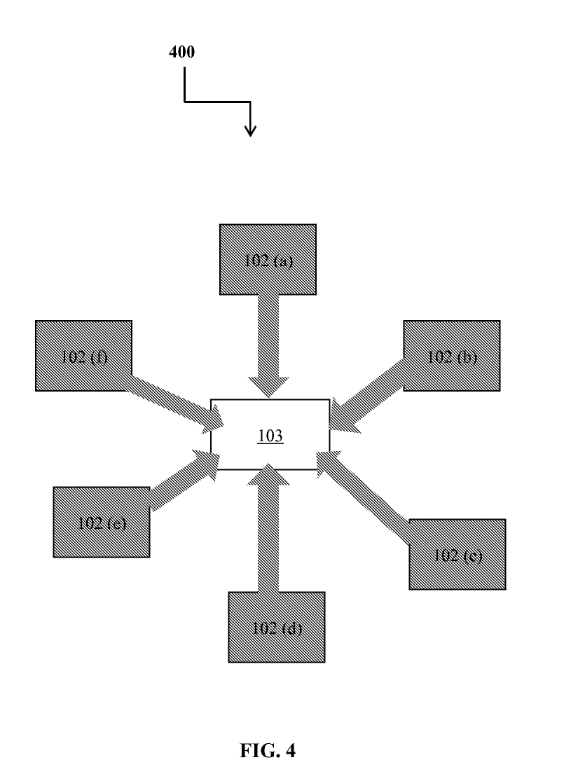

FIG. 4 is a schematic view of a fluid leakage detection system 400, including multiple fluid leakage sensors 102(a)-102(f). Each sensor is coupled to a central alarming system 103, according to another embodiment of the present disclosure. The fluid leakage sensors 102(a)-(f) may be installed at different regions of the vehicle where monitoring and prevention of fluid leakage is required or intended. Each of the fluid leakage sensors 102(a)-(f) is configured to continuously detect fluid leakage at a specific location in the vehicle.

The structure and the integral components of each of the fluid leakage sensors 102(a)-(f) may be similar to that of the fluid leakage sensor 102 explained in connection with FIG. 1. Specifically, each of the fluid leakage sensors 102(a)-(f) has an electrical circuit 104, having a first portion 106 disposed in a non-conductive absorbent material, and a second portion 108 connected to the first portion and positioned exterior to the non-conductive body 101. The non-conductive body 101 of each sensor is configured to absorb fluid leaking from a specific region of the vehicle where that sensor is disposed. The absorption of leaking fluid from that region establishes an electric current within the electrical circuit 104 of that sensor, and the established current flows through the central alarming system 103. The alarming system 103 generates a verbal signal, an audio signal or a visual signal, as mentioned earlier, to notify the user.

The central alarm system 103 includes a central processing unit, which is capable of distinguishing signals received from the different fluid leakage sensors 102(a)-(f), to correctly identify the region of the vehicle where a fluid leakage has been detected. To affect distinguishing of signals received from different leakage sensors, each of the sensors 102(a)-(f) may be coupled to a specific identifiable input port of the alarming system 103, in an embodiment. Further, if simultaneous leakage is detected at two or more region of the vehicle, the central alarming system 103 is capable of generating notifications pertaining to identification of those fluid leakage regions. In an embodiment, leakage identified at different regions may be distinguishable through alarm beeps of different loudness/frequency, accompanied by a verbal message notifying the corresponding regions of leakage. Further, the central alarming system 103 may deactivate the notifying message after a certain time, to allow sufficient time to fix the leakage. Further, as mentioned earlier, the central alarming system 103 maybe in the form of a user display interface provided at an appropriate portion of a vehicle, which displays the fluid leakage status of each region where the sensors 102(a)-(f) are installed. In an embodiment, the central alarming system 103 may be a part of a vehicle condition monitoring system, so that the presence of fluid in the regions can be checked during periodic vehicle maintenance visits.

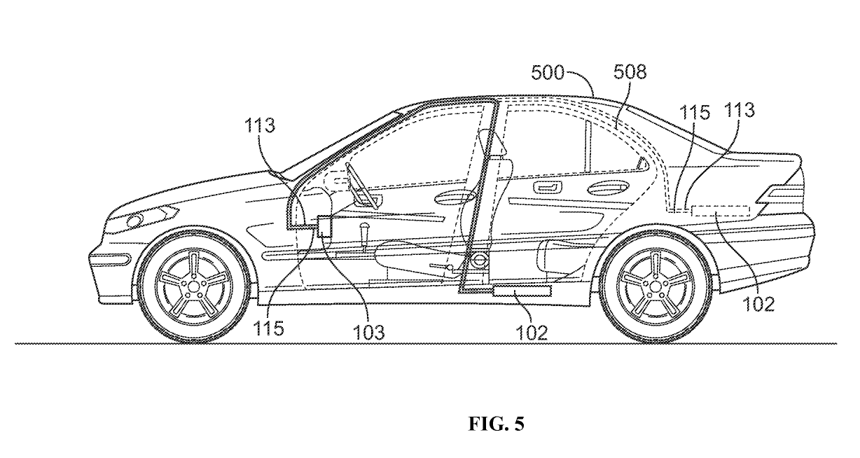

FIG. 5 is a side view of a vehicle 500, having a fluid leakage detection system of the present disclosure installed at one or more portions of the vehicle. One fluid leakage sensor 102 is positioned at a lower portion of the vehicle 500, proximal to the rear left door 508 of the vehicle, as shown. Another sensor 102 is disposed at a rear portion of the vehicle 500, i.e., within the trunk of the vehicle, where fluid leakage can possibly occur. The illustrated positions of installation of the fluid leakage sensors 102 are only exemplary, and it is contemplated that the sensors 102 may also be installed at any other suitable location within the vehicle 500, where fluid is expected to leak and accumulate. Further, though only two such sensors have been depicted, any number of such sensors 102 may be used to detect fluid leakage at different regions of potential fluid leakage within a vehicle.

Each sensor 102 includes a non-conductive body 101 composed of a suitable absorbent material (not shown), configured to absorb and collect leaking fluid from the respective portions. The insulated wires 113 and 115, composing the second portion 108 of the electrical circuit of the sensors 102, are coupled to the sensors 102 at one end, and are eventually coupled at other end to an alarming system 103 positioned at the front portion of the vehicle. The wires 113 and 115 may be routed through the B-Pillar or the C-pillar of the vehicle 500, to connect to the alarming system 103. Other suitable paths for routing the insulated wires 113 and 115 from the sensors 102, towards the central alarming system 103 may also be contemplated. The alarming system 103 may be positioned at the front portion of the vehicle 500, such as proximal to, or underneath the front dashboard of the vehicle 500. However, based on user's priority, the alarming system 103 may also be positioned at any other suitable location within the vehicle 500. In certain embodiments, the alarming system 103 may be coupled to a display interface (not shown) positioned over the frontal portion of the vehicle 500. The display interface may be configured to display verbal signals when any fluid leakage is detected.

The fluid leakage detection system of the present disclosure is capable of detecting fluid leakage occurring at any portion of a vehicle, and is flexible enough to be installed at contoured surfaces of the vehicle where conventional leakage detection systems are relatively difficult to install. Further, as mentioned earlier, the system has a capacity to detect even minute drops of fluid leaking at any region of the vehicle. Also, though being explained in context of an automotive vehicle, the system can also be used to detect leakage of fluid in other environments. Additionally, the system is compatible with, and works efficiently to detect leakage of any electrically conductive fluid.

Although the current invention has been described comprehensively, in considerable details to cover the possible aspects and embodiments, those skilled in the art would recognize that other versions of the invention are also possible.

What is claimed is:

1. A fluid leakage sensor comprising:
an electrically non-conductive body formed of an absorbent material, and positioned to collect and absorb a leaking electrically conductive fluid; and
an electrical circuit including at least two spaced-apart, uninsulated electrical conductive members lying within the non-conductive body and arranged such that the presence of the leaking fluid produces a closed circuit between the conductive members.

2. The fluid leakage sensor of claim 2, wherein the non-conductive body includes a surface exposed to the leakage path of the leaking fluid; and the electrical circuit is arranged in a pattern substantially covering the surface.

3. The fluid leakage sensor of claim 1, wherein the electrical circuit is arranged in a predetermined pattern.

4. The fluid leakage sensor of claim 1, wherein each conductive member includes a bare portion and an insulated portion.

5. The fluid leakage sensor of claim 4, wherein the bare portion of each conductive members is embedded and spread within the non-conductive body, to cover a substantial area of the non-conductive body, and to form the first portion of the electrical circuit.

6. The fluid leakage sensor of claim 4, wherein the insulated portion of each conductive member extends outwards from the non-conductive body, to form the second portion of the electrical circuit.

7. The fluid leakage sensor of claim 4, wherein the bare portions of each conductive member is embedded within the non-conductive body in a predetermined pattern, the pattern maintaining minimum distance between the bare portions throughout the pattern.

8. The fluid leakage sensor of claim 4, wherein the bare portions of each member is electrically decoupled in the absence of leaking fluid, and are configured to be electrically coupled on the absorption of leaking fluid by the non-conductive body.

9. The fluid leakage sensor of claim 1, further comprising a power source configured to supply electrical power to the electrical circuit of the fluid leakage sensor.

10. The fluid leakage sensor of claim 1, wherein the non-conductive body is formed of a flexible material.

11. The fluid leakage sensor of claim 1, wherein the non-conductive body is formed of one of woven fibers, felted fibers, or polymeric foam.

12. The fluid leakage detection system of claim 12, wherein the non-conductive body is impregnated with a non-aqueous soluble salt.

13. A fluid leakage detection system for a vehicle, comprising:
a plurality of the fluid leakage sensors of claim 1, each sensor positioned at a position within the vehicle where an electrically conductive fluid is expected to leak and accumulate;
a central alarming system operably coupled to each fluid leakage sensor, the alarming system configured to generate signals indicating activation of one or more fluid leakage sensors.

14. A fluid leakage detection system for detecting leakage of an electrically conductive fluid from one or more portions of a vehicle, the system comprising:
at least one fluid leakage sensor, including:
an electrically non-conductive body formed of an absorbent material, and positioned to collect and absorb a leaking electrically conductive fluid; and
an electrical circuit including at least two spaced-apart, uninsulated electrical conductive members lying within the non-conductive body and arranged such that the presence of the leaking fluid produces a closed circuit between the conductive members;
a power source configured to supply electrical power to each sensor; and
a central alarming system operably coupled to each fluid leakage sensor, the alarming system configured to generate signals indicating activation of one or more fluid leakage sensors.

15. The fluid leakage detection system of claim 14, wherein the non-conductive body includes a surface exposed to the leakage path of the leaking fluid; and the electrical circuit is arranged in a pattern substantially covering the surface.

16. The fluid leakage detection system of claim 14, wherein the electrical circuit is arranged in a predetermined pattern.

17. The fluid leakage detection system of claim 14, wherein each conductive member includes a bare portion and an insulated portion.

18. The fluid leakage detection system of claim 14, wherein the bare portion of each conductive member is embedded and spread within the non-conductive body, covering a substantial area of the non-conductive body.

19. The fluid leakage detection system of claim 14, wherein the bare portion of each conductive member is embedded within the non-conductive body in a predetermined pattern, the pattern maintaining minimum distance between the bare portions throughout the pattern.

20. The fluid leakage detection system of claim 14, wherein the bare portions of the conductive members are electrically decoupled in the absence of leaking fluid, and are configured to be electrically coupled upon the absorption of leaking fluid by the non-conductive body.
